(19) United States
(12) Patent Application Publication
(10) Pub. No.: US 2012/0126352 A1
(43) Pub. Date: May 24, 2012

(54) METHOD FOR MANUFACTURING SEMICONDUCTOR CHIPS, MOUNTING METHOD AND SEMICONDUCTOR CHIP FOR VERTICAL MOUNTING ONTO CIRCUIT SUBSTRATES

(76) Inventors: Hans-Peter Baer, Pfullingen (DE); Paul Farber, Stuttgart (DE); Stefan Weiss, Tuebingen (DE); Lutz Rauscher, Reutlingen (DE)

(21) Appl. No.: 13/291,278

(22) Filed: Nov. 8, 2011

(30) Foreign Application Priority Data
Nov. 23, 2010 (DE) 102010061770.9

(51) Int. Cl. H01L 29/82; H01L 21/50; H01L 21/78

(52) U.S. Cl. 257/421; 438/460; 438/106; 257/E21.599; 257/E29.323; 257/E21.499

(57) ABSTRACT

A semiconductor chip having contact surfaces on an upper side parallel to the wafer plane has terminal pads on a terminal-pad side perpendicular to the upper side, each terminal pad being conductively connected to an assigned contact surface. This allows vertical mounting of the chip on a substrate and contacting with the aid of customary bonding techniques. A manufacturing method and two mounting methods are described.

### CROSS REFERENCE

The present application claims the benefit under 35 U.S.C. §119 of German Patent Application No. DE 102010061770.9 filed on Nov. 23, 2010, which is expressly incorporated herein by reference in its entirety.

### FIELD OF THE INVENTION

The present invention relates to a method for manufacturing semiconductor chips, mounting method and a semiconductor chip for vertical mounting onto circuit substrates.

### BACKGROUND INFORMATION

Electronic circuits and mechanical or magnetic sensors in silicon technology are normally packaged in so-called chip packages, which allows them, inter alia, to be easily soldered on circuit boards for installation in devices or modules. To that end, the silicon chips are normally sawed and, using various methods, mounted onto the substrates, such as pressed screen or circuit boards, of the chip packages and electrically connected, either simultaneously or in a separate step. In this context, the chips are assembled in the plane in which they are also situated on the silicon wafer during the manufacturing process. Therefore, generally, the height of the chips is the smallest dimension of the block-shaped chips. For some applications of the sensor technology, it may be advantageous to mount individual chips in the chip package in a direction perpendicular to the plane in which they are situated on the wafer.

An option for mounting, for example, magnetic field sensor chips in the chip package in this manner, perpendicular to their manufacturing direction, is described in U.S. Pat. No. 7,095,226 B2. There, design approaches are described for vertically mounting chips, whose terminal areas, bond pads, are positioned in the same manner as is customary for parallel mounting, that is, in the plane of the silicon wafer that is consequently perpendicular to the mounting base area after mounting. These chips cannot be connected, using the customary connecting technique for terminal pads parallel to the mounting base area. P.C.T. Application No. WO 2008/016198 describes a vertically mounted sensor chip having bonding areas on a front side, but no information is given regarding manufacturing or mounting.

### SUMMARY

An example method of the present invention for manufacturing semiconductor chips, the mounting method and the semiconductor chip for vertical mounting on circuit substrates may have the advantage that the chips manufactured in this manner may be mounted in so-called chip packages in a highly uncomplicated manner, in a direction perpendicular to the wafer plane. In this context, the terminal areas, i.e., bonding pads, are situated parallel to the substrate of the chip package, as in the case of customary horizontal mounting, which means that customary methods such as wire bond, flip-chip, etc. may be used for the electrical contacting.

A further advantage of the present invention is to provide chips, in particular, silicon chips, with terminal areas (bond pads) on a surface perpendicular to the wafer plane before the wafer is separated into chips.

### BRIEF DESCRIPTION OF THE DRAWINGS

Exemplary embodiments of the present invention are described in light of the figures.

FIG. 1 shows a schematic representation of a ready-sawed chip having terminal pads perpendicular to the upper side lying parallel to the wafer, according to a specific embodiment of the present invention.

FIG. 2 shows a flow chart of the method for manufacturing semiconductor chips according to a specific embodiment of the present invention.

FIG. 3 shows a schematic representation of a cut-off detail of a wafer in different manufacturing stages, according to the method shown in FIG. 2.

FIG. 4 shows a schematic representation of a plan view of a detail of a wafer prior to sawing, according to a specific embodiment of the present invention.

FIG. 5 shows a schematic representation of a plan view of a detail of a wafer prior to sawing, according to a further specific embodiment of the present invention.

FIG. 6 shows a flow chart of the mounting method of a semiconductor chip bonded to wires, according to a specific embodiment of the present invention.

FIG. 7 shows a schematic representation of a semiconductor chip vertically mounted on a substrate and bonded to wires, according to a specific embodiment of the present invention.

FIG. 8 shows a flow chart of the mounting method of a semiconductor chip, which is mounted vertically on a substrate, using flip-chip technology, according to a specific embodiment of the present invention.

FIG. 9 shows a schematic representation of a semiconductor chip, which is vertically mounted on a substrate, using flip-chip technology, according to a specific embodiment of the present invention.

### DETAILED DESCRIPTION OF EXAMPLE EMBODIMENTS

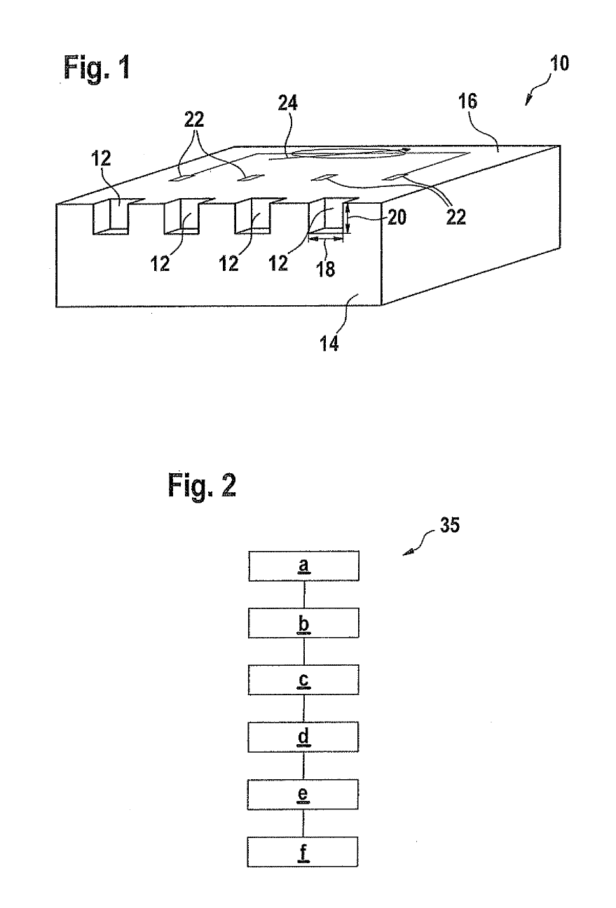

FIG. 1 shows a ready-sawed chip 10 having terminal pads 12 on a terminal-pad side 14 perpendicular to an upper side 16 lying parallel to the wafer. During the mounting in the chip package, chip 10 is rotated 90°, and terminal-pad side 14 will lie parallel to a circuit substrate. Terminal pads 12 have a width 18 and height 20 that correspond to a typical bonding pad, i.e., 50 μm to 150 μm. Contact surfaces 22 are situated on upper side 16 of chip 10, the contact surfaces being connected to circuits of the chip that are represented by circuit 24. In the manufacturing method of the chip, each terminal pad 12 is connected to a contact surface 22 (the connections are not shown).

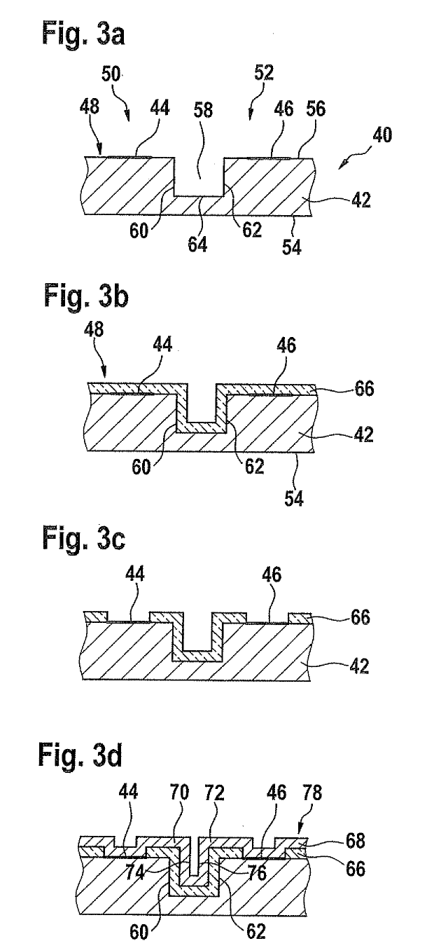

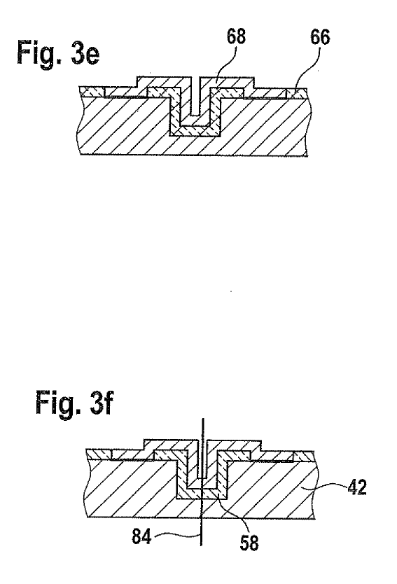

In FIG. 2, flow chart 35, together with the schematic representation of a cut-out detail 40 of a wafer 42 shown in FIG. 3 in different manufacturing stages a) through f), explains an example method for manufacturing semiconductor chips, such as chip 10 from FIG. 1, according to a specific embodiment of the present invention. The example method starts out from a semiconductor wafer 42 having rows of chips having contact surfaces 44, 46 on an active upper surface 48, the chips being separated from one another by saw lines. Detail 40 shows a section in the region of, and perpendicular to, a saw line, the section showing outer parts of two chips, contact surface 44 being assigned to circuits of a first chip 50, and contact surface 46 being assigned to circuits of a second chip 52. Active upper surface 48 is, in each instance, the open surface on upper side 56 of the wafer, opposite to wafer back side 54, the active upper surface being processed and, consequently, shaped and displaced in accordance with the method steps. Intermediate method steps, such as the deposition and removal of photoresist material, are not shown, since they are conventional. In this case, the wafer is a silicon wafer, but the method is also suitable for other wafer materials, one skilled in the art selecting the technique and chemicals appropriate for the wafer material for the specific method step may be selected.

FIG. 3a shows detail 40 having the terminal area of semiconductor chips after the method step:

a) production of generally block-shaped depressions 58 along a saw line, the depressions having at least one major surface 60, 62 perpendicular to upper side 56 and parallel to the saw line. The generally block-shaped depressions 58 have been produced by the DRIE process (deep reactive-ion etching) and have a lower side 64 in wafer 42. Terminal pads will be formed on major surfaces 60, 62 in the continuing method.

FIG. 3b shows detail 40 after the method step that follows now:

b) deposition of an insulating layer 66 on active upper surface 48, including at least one major surface, in this case, the two major surfaces 60, 62. A preferred material for the insulating layer is silicon dioxide.

FIG. 3c shows detail 40 after the method step that follows now:

c) removal of insulating layer 66 over contact surfaces 44, 46.

FIG. 3d shows detail 40 after the method step that follows now:

d) deposition of a metallic layer 68 on the active upper surface and major surfaces 60, 62 to produce a conductive connection 70, 72 of contact surfaces 44, 46 to terminal pads 74, 76 on major surfaces 60, 62. Region 78 of metallic layer 68 forms a conductive connection to an adjacent terminal pad. Metallic layer 68 is deposited onto all five surfaces of block-shaped depressions 58. The metallic layer is deposited by a PVD method (physical vapor deposition).

FIG. 3e shows detail 40 after the method step that follows now:

e) patterning of metallic layer 68 by removing the metallic layer between conductive connections of adjacent terminal pads. The removal of the metallic layer is accomplished by lithography, using a spray-resist method and a customary metal etching method.

FIG. 3f shows detail 40 in the method step that follows now:

f) sawing of semiconductor wafer 42, using a saw cut 84 through depressions 58. Chips 50 and 52 are now separated from one another.

According to a further embodiment of the present invention, the deposition and patterning of the metallic layer in method steps d) and e) may be accomplished, using an x-ray lithography masking method.

In this example, the semiconductor chip is a magnetic field sensor, which may be mounted vertically to produce, in particular, a 3-D magnetic field sensor.

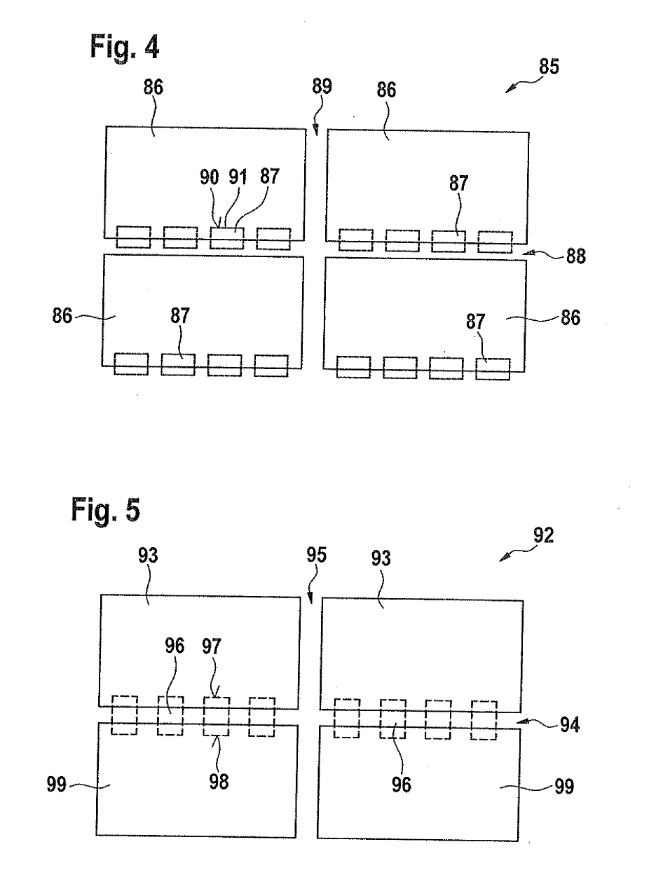

FIG. 4 shows a detail 85 of a wafer having four chips 86, as well as the positions of block-shaped depressions 87 on the wafer prior to sectioning. Saw lines 88, 89 are the regions of the wafer that are removed by sawing and are typically several tens of μm wide, depending on the width of the saw blade. Depressions 87 are positioned in such a manner, that chips according to FIG. 1 are formed after sawing. Metallic layer 68 in FIG. 3d is deposited onto all five surfaces of block-shaped depressions 87. However, in this specific embodiment, only one major surface 90 of depressions 87 is used as a terminal pad 91. Saw line 88 runs through depressions 87. The metallic layers of the sides of depressions 87 not used as a terminal pad remain. The patterning of the metallic layer and the saw cut allow the terminal pads of adjacent depressions to be isolated from one another.

FIG. 5 shows a detail 92 of a wafer having four chips 93, 99, as well as the positions of block-shaped depressions 96 on the wafer prior to sectioning. Depressions 96 are positioned in such a manner, that chips according to FIG. 1 are formed after sawing along saw lines 94, 95. In this specific embodiment, the two major surfaces 97, 98 of the depressions are used as terminal pads, as shown already in FIG. 3. Saw line 94 runs through depressions 96. The chips of every second chip row are rotated by 180°, in this case, chips 99 in comparison with chips 93; and upon being sawed through, one depression 96 produces two terminal pads on two diametrically opposed chips.

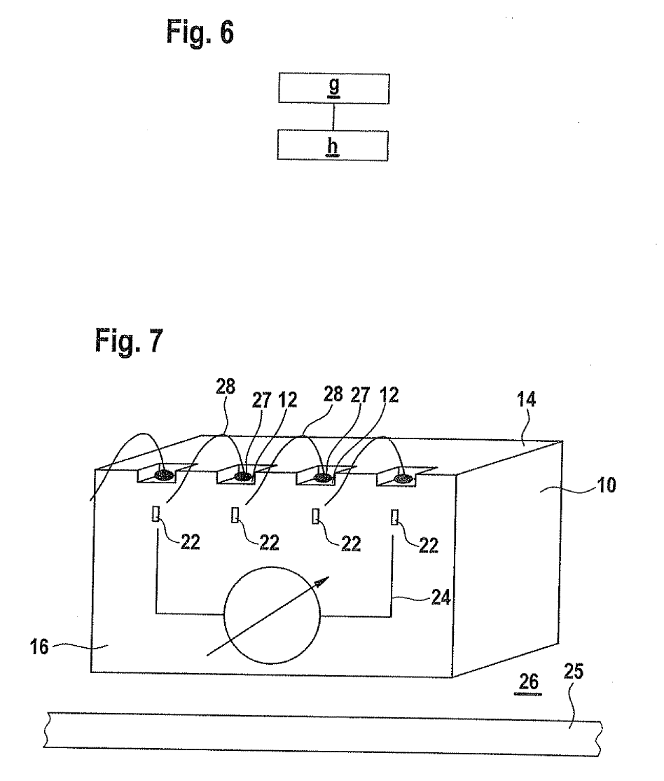

A flow chart of a mounting method of a semiconductor chip bonded to wires is depicted in FIG. 6, and FIG. 7 shows the semiconductor chip from FIG. 1, correspondingly mounted. The method for mounting semiconductor chips 10, which have terminal pads 12, so-called bonding areas, on a terminal-pad upper surface or bonding-area upper surface 14 perpendicular to an upper side 16 of the wafer, to a substrate 25 having connecting surfaces on the substrate that are parallel to a substrate upper side 26, begins with the method step:

g) mounting of semiconductor chip 10 with a surface, which is opposite to bonding-area upper surface 14, on substrate upper side 26. The connecting surface may also be situated on a different component on substrate 25.

The following method step comes next:

h) automated connecting of, in each instance, one terminal pad 12 to one connecting surface, using one connecting wire. FIG. 7 shows ready-sawed semiconductor chip 10 in the orientation for mounting in the chip package, the semiconductor chip having bonding wires (wire bonds) 28 bonded onto terminal pads 12 with the aid of soldering points 27.

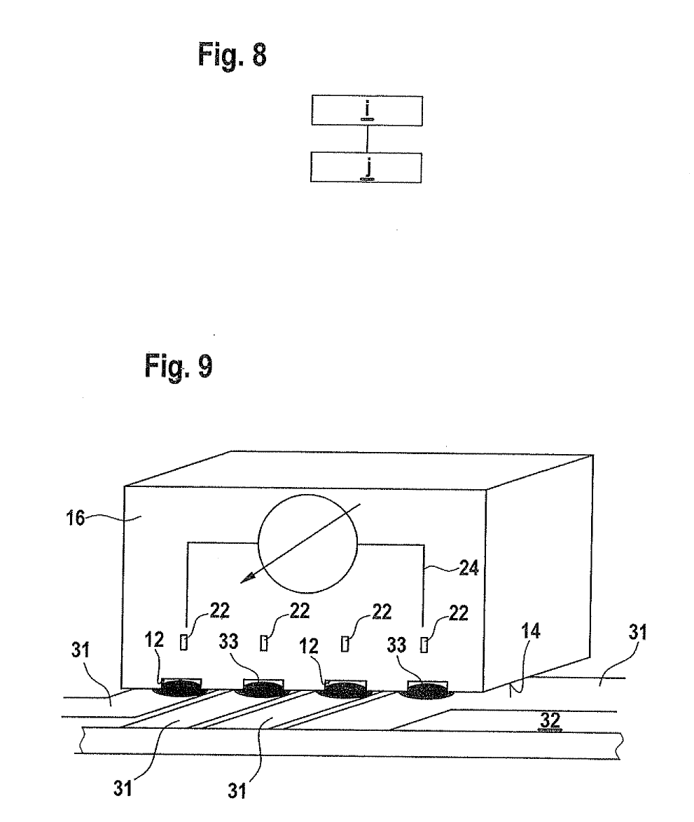

A flow chart of the mounting method of a semiconductor chip vertically mounted on a substrate, using flip-chip technology, is represented in FIG. 8, and FIG. 9 shows the semiconductor chip from FIG. 1, correspondingly mounted. The method for mounting semiconductor chips 10, which have terminal pads 12 on a terminal-pad upper surface 14 perpendicular to an upper side 16 of the wafer, to a substrate 30 having connecting surfaces on conductor tracks 31 on a substrate upper side 32, begins with the method step:

i) positioning of semiconductor chip 10 with bonding-area upper surface 14 on substrate upper surface 32. The connecting surface may also be situated on a different component on substrate 25.

The following method step comes next:

j) connecting of terminal pads 12 to connecting surfaces, using a soldering method. FIG. 9 shows ready-sawed semiconductor chip 10 in the orientation for mounting in the chip package, during contacting with the aid of solder balls 33 (flip-chip method).

Consequently, semiconductor chip 10 is suitable for contacting by customary methods in accordance with conventional bonding wire technology and flip-chip technology, when the chip is positioned in such a manner, that bonding areas 12, which are situated on a bonding-area upper surface 14 that is perpendicular to upper side 16 of the wafer, are oriented parallel to connecting surfaces on a substrate upper surface.

What is claimed is:

1. A method for manufacturing semiconductor chips for vertical mounting onto circuit substrates, starting from a semiconductor wafer having rows of chips having contact surfaces on an upper side, the chips being separated from one another by saw lines, the method comprising:
producing generally block-shaped depressions along a saw line, the depressions having at least one major surface perpendicular to the upper side and parallel to the saw line;
depositing an insulating layer on an active upper surface of the wafer, including on at least one major surface of the depressions;
removing the insulating layer over contact surfaces;
depositing a metallic layer on the active upper surface and the major surface to produce a conductive connection of contact surfaces to the major surfaces;
patterning the metallic layer by removing portions of the metallic layer between conductive connections of adjacent major surfaces; and
sawing the semiconductor wafer using a saw cut through the depressions.

2. The method as recited in claim 1, wherein the generally block-shaped depressions are produced using a deep reactive-ion etching process (DRIE).

3. The method as recited in claim 1, wherein the depositing of the metallic layer is carried out using a PVD method.

4. The method as recited in claim 1, wherein the removing of the portions of the metallic layer is carried out by lithography using a spray resist method.

5. The method as recited in claim 1, wherein the depositing and patterning of the metallic layer is carried out using an x-ray lithography masking method.

6. The method as recited in claim 1, wherein the chips of every second row are rotated by 180°, and the depressions have two diametrically opposed, major surfaces, which are allocated to different chips.

7. The method as recited in claim 1, wherein the semiconductor wafer is a silicon wafer.

8. A semiconductor chip having contact surfaces on an upper side parallel to a wafer plane, and having terminal pads on a terminal-pad side perpendicular to the upper side, wherein each terminal pad is conductively connected to an assigned contact surface.

9. The semiconductor chip as recited in claim 8, wherein the semiconductor chip is a magnetic field sensor.

10. A method for mounting semiconductor chips, which have bonding areas on a bonding-area upper surface perpendicular to an upper side of the wafer, to a substrate having terminal pads on conductor tracks on a substrate upper side, the method comprising:
positioning a semiconductor chip with the bonding-area upper surface on the substrate upper surface; and
connecting terminal pads to connecting surfaces using a soldering method.

11. The mounting method as recited in claim 10, wherein the soldering method is executed using solder balls.
